(19) United States
(12) Patent Application Publication
(10) Pub. No.: US 2020/0090980 A1
(43) Pub. Date: Mar. 19, 2020

(54) METHOD FOR PREPARING SEMICONDUCTOR STRUCTURES

(71) Applicant: NANYA TECHNOLOGY CORPORATION, New Taipei City (TW)

(72) Inventor: SHING-YIH SHIH, NEW TAIPEI CITY (TW)

(21) Appl. No.: 16/130,348

(22) Filed: Sep. 13, 2018

(51) Int. Cl. H01L 21/762; H01L 21/02

(52) U.S. Cl. CPC H01L 21/76224; H01L 21/02639; H01L 21/02505; H01L 21/02381

(57) ABSTRACT

The present disclosure provides a method for preparing semiconductor structures. The method includes the following steps. A substrate is provided. A plurality of first trenches are formed in the substrate. A first initially-flowable layer is formed in the plurality of first trenches. A top surface of the first initially-flowable layer is lower than openings of the plurality of first trenches. A first treatment is performed on the first initially-flowable layer to form a first dielectric layer in the plurality of first trenches. A second initially-flowable layer is formed to fill the plurality of first trenches. A second treatment is performed on the second initially-flowable layer to form a second dielectric layer in the plurality of first trenches.

### TECHNICAL FIELD

The present disclosure relates to a method for preparing semiconductor structures, and more particularly, to a method for preparing semiconductor island structures.

### DISCUSSION OF THE BACKGROUND

In semiconductor manufacturing processes, photolithography techniques are commonly adopted to define structures. Typically, an integrated circuit layout is designed and outputted onto one or more photomasks. The integrated circuit layout is transferred from the photomasks to a mask layer to form a mask pattern, and then transferred from the mask pattern to a target layer. However, with the advancing miniaturization and integration requirements of semiconductor devices, including memory devices such as dynamic random access memories (DRAMs), flash memories, static random access memories (SRAMs), and ferroelectric (FE) memories, the semiconductor structures and features of such devices become more miniaturized as well. Accordingly, the continual reduction in semiconductor structure and feature sizes places ever-greater demands on the techniques used to form the structures and features.

For example, to form active regions in the substrate, a plurality of trenches are formed by etching the substrate, and a plurality of island structures, which are used to form the active regions, are obtained and separated from each other by the trenches. Insulating materials are then deposited to fill the trenches and to form a plurality of isolation structures to define and provide electrical isolation between the island structures. However, it is often found that the island structures may collapse due to stress from the insulating material filled therebetween. Consequently, reliability and performance of a device that includes an island structure and an active region are reduced.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a method for preparing semiconductor structures. The method includes the following steps. A substrate is provided. A plurality of first trenches are formed in the substrate. A first initially-flowable layer is formed in the plurality of trenches. In some embodiments, a top surface of the first initially-flowable layer is lower than openings of the plurality of first trenches. A first treatment is performed on the first initially-flowable layer to form a first dielectric layer in the plurality of trenches. A second initially-flowable layer is formed to fill the plurality of first trenches. A second treatment is performed on the second initially-flowable layer to form a second dielectric layer in the plurality of first trenches.

In some embodiments, the first treatment includes a first thermal treatment.

In some embodiments, the second treatment includes a second thermal treatment, and a temperature of the second thermal treatment is lower than a temperature of the first thermal treatment.

In some embodiments, the temperature of the first thermal treatment is between approximately 200° C. and approximately 400° C.

In some embodiments, the temperature of the second thermal treatment is between approximately 100° C. and approximately 300° C.

In some embodiments, the first treatment includes a UV curing treatment and a wet rinse.

In some embodiments, the first treatment includes an ozone (O₃) oxidation.

In some embodiments, the second treatment includes a UV curing treatment and a wet rinse.

In some embodiments, the second treatment includes an O₃ oxidation.

In some embodiments, the method further includes forming at a plurality of second trenches in the substrate simultaneously with the forming of the plurality of first trenches.

In some embodiments, a width of the plurality of second trenches is greater than a width of the plurality of first trenches.

In some embodiments, the first initially-flowable layer is formed in the plurality of second trenches. In some embodiments, a top surface of the first initially-flowable layer is lower than openings of the plurality of second trenches.

In some embodiments, the top surface of the first initially-flowable layer in the plurality of first trenches is higher than the top surface of the first initially-flowable layer in the plurality of second trenches.

In some embodiments, a difference exists between the top surface of the first initially-flowable layer in the plurality of first trenches and the top surface of the first initially-flowable layer in the plurality of second trenches. In some embodiments, the difference is between approximately 10 nm and approximately 50 nm.

In some embodiments, the first initially-flowable layer and the second initially-flowable layer include a flowable semiconductor-containing layer.

In some embodiments, the first initially-flowable layer and the second initially-flowable layer include a same material.

In some embodiments, the method further includes performing a densification after the forming of the second dielectric layer.

In some embodiments, the method further includes performing a planarization after the forming of the second dielectric layer.

In the present disclosure, the first initially-flowable layer and the second initially-flowable layer are sequentially formed and treated to form the first and second dielectric layers. Therefore, the first trenches are partially filled with the first dielectric layer and then completely filled with the second dielectric layer. In other words, a dielectric structure formed of the first and second dielectric layer is obtained by two steps. As a result, stress generated by filling the trenches is reduced. Consequently, collapse of semiconductor structures separated by the first dielectric layer and the second dielectric layer is mitigated and performance of a device that includes the semiconductor structures is improved.

In contrast, with a comparative method applied with forming the dielectric structure in one step, the dielectric structure used to isolate semiconductor structures faces a necessary compromise. To provide sufficient electrical isolation, a higher temperature is required to form a dense structure, and significant stress is generated at the higher temperature, thus causing the collapse issue. To avoid the collapse issue, lower temperature is required, but the dielectric structure then suffers from void issue and poor electrical isolation. Ultimately, therefore, the semiconductor structures suffer from either the collapse issue or the poor electrical isolation.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a flow diagram illustrating a method for preparing semiconductor structures, in accordance with some embodiments of the present disclosure.

FIGS. 2A, 3A, 4A, 5A, 6A, 7A and 8A are schematic diagrams illustrating various fabrication stages of the method for preparing the semiconductor structures in accordance with a first embodiment of the present disclosure.

FIGS. 2B, 3B, 4B, 5B, 6B, 7B and 8B are cross-sectional views taken along line I-I′ and line II-II′ in FIGS. 2A, 3A, 4A, 5A, 6A, 7A and 8A, respectively.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

As used herein, the terms “patterning” or “patterned” are used in the present disclosure to describe an operation of forming a predetermined pattern on a surface. The patterning operation includes various steps and processes and varies in accordance with different embodiments. In some embodiments, a patterning process is adopted to pattern an existing film or layer. The patterning process includes forming a mask on the existing film or layer and removing the unmasked film or layer with an etch or other removal process. The mask can be a photoresist or a hard mask. In some embodiments, a patterning process is adopted to form a patterned layer directly on a surface. The patterning process includes forming a photosensitive film on the surface, conducting a photolithography process, and performing a developing process. The remaining photosensitive film is retained and integrated into the semiconductor device.

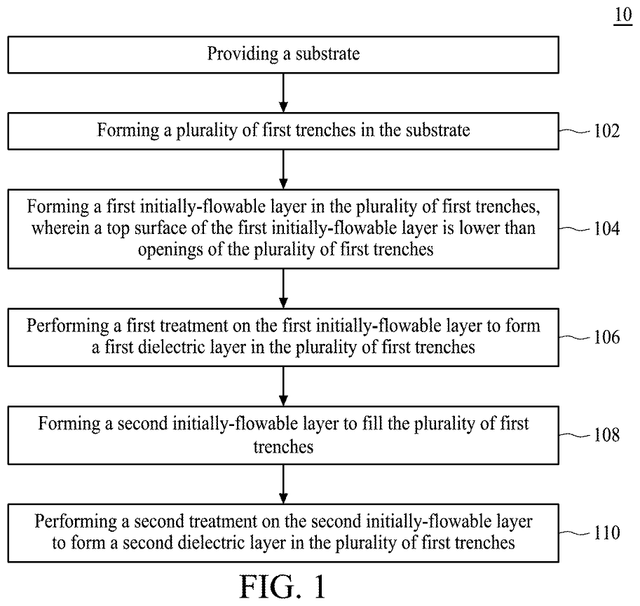

FIG. 1 is a flow diagram illustrating a method for preparing semiconductor structures, in accordance with some embodiments of the present disclosure. The method for preparing semiconductor structures 10 includes a step 100, providing a substrate. The method for preparing the semiconductor structures 10 further includes a step 102, forming a plurality of first trenches in the substrate. The method for preparing the semiconductor structures 10 further includes a step 104, forming a first initially-flowable layer in the plurality of first trenches. In some embodiments, a top surface of the first initially-flowable layer is lower than openings of the plurality of first trenches. The method for preparing the semiconductor structures 10 further includes a step 106, performing a first treatment on the first initially-flowable layer to form a first dielectric layer in the plurality of first trenches. The method for preparing the semiconductor structures 10 further includes a step 108, forming a second initially-flowable layer to fill the plurality of first trenches. The method for preparing the semiconductor structures 10 further includes a step 110, performing a second treatment on the second initially-flowable layer to form a second dielectric layer in the plurality of first trenches. The method for preparing the semiconductor structures 10 will be further described according to one or more embodiments.

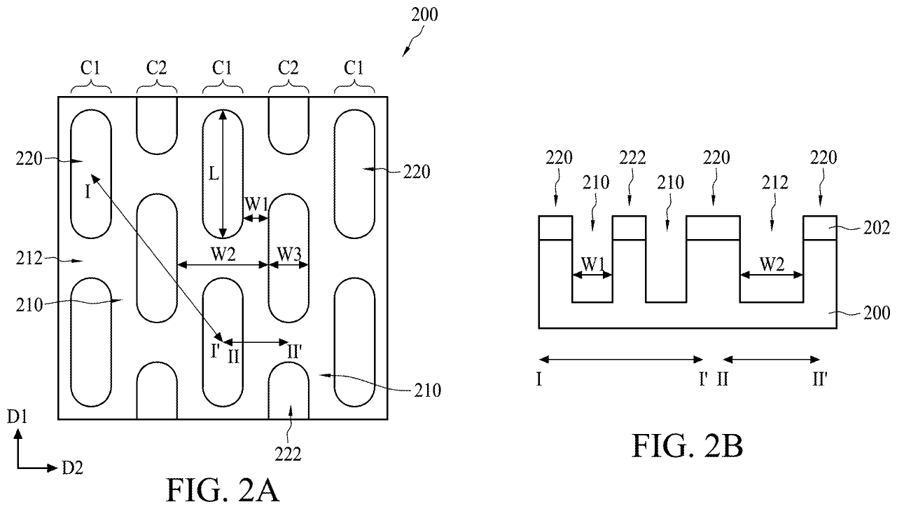

FIGS. 2A, 3A, 4A, 5A, 6A, 7A and 8A are schematic diagrams illustrating various fabrication stages constructed according to the method for preparing the semiconductor structures in accordance with some embodiments of the present disclosure, and FIGS. 2B, 3B, 4B, 5B, 6B, 7B and 8B are cross-sectional views taken along line I-I′ and line II-II′ in FIGS. 2A, 3A, 4A, 5A, 6A, 7A and 8A, respectively. Referring to FIGS. 2A and 2B, a substrate 200 is provided according to step 100. The substrate 200 can include silicon (Si), gallium (Ga), gallium arsenide (GaAs), gallium nitride (GaN), strained silicon, silicon-germanium (SiGe), silicon carbide (SiC), diamond, epitaxy layer or a combination thereof, but the disclosure is not limited thereto.

Referring to FIGS. 2A and 2B, a patterned hard mask 202 is formed on the substrate 200. In some embodiments of the present disclosure, the patterned hard mask 202 can include a single-layer or multi-layered structure. The pattered hard mask 202 may include a pattern for defining a location and a dimension of an isolation structure. Next, portions of the substrate 200 are removed through the patterned hard mask 202, and thus a plurality of first trenches 210 are formed in the substrate 200, according to step 102. In some embodiments, a plurality of second trenches 212 can be formed in the substrate 200 simultaneously with the forming of the plurality of first trenches 210, as shown in FIGS. 2A and 2B. In some embodiments, the plurality of first trenches 210 and the plurality of second trenches 212 have a same depth, but the disclosure is not limited thereto. In some embodiments, a width W2 of the plurality of second trenches 212 is greater than a width W1 of the plurality of first trenches 210, as shown in FIGS. 2A and 2B. In some embodiments, the width W2 of the plurality of second trenches 212 is at least three times the width W1 of the plurality of first trenches 210, but the disclosure is not limited thereto. In some embodiments, the width W1 of the plurality of first trenches 210 is less than 30 nm, but the disclosure is not limited thereto. Further, as shown in FIG. 2A, the plurality of first trenches 210 and the plurality of second trenches 212 are coupled to each other to form a grid.

Still referring to FIGS. 2A and 2B, the grid formed by the plurality of first trenches 210 and the plurality of second trenches 212 further defines a plurality of first island structures 220 and a plurality of second island structures 222. In other words, the plurality of first trenches 210, the plurality of second trenches 212, the plurality of first island structures 220 and the plurality of second island structures 222 are simultaneously formed in step 102. The plurality of first island structures 220 and the plurality of second island structures 222 include a same length L and a same width W3. In some embodiments, the width W3 of the plurality of first island structures 220 and the plurality of second island structures 222 can be equal to or greater than the width W1 of the first trenches 210, but less than the width W2 of the plurality of second trenches 212. As shown in FIG. 2A, the plurality of first island structures 220 are arranged along a first direction D1 to form a plurality of first columns C1, and the plurality of second island structures 222 are arranged along the first direction D1 to form a plurality of second columns C2. It should be noted that the first columns C1 and the second columns C2 are alternately arranged along a second direction D2, and the second direction D2 is different from the first direction D1. In some embodiments, the second direction D2 is perpendicular to the first direction D1, but the disclosure is not limited thereto. As shown in FIGS. 2A and 2B, along the second direction D2, the first island structures 220 and the second island structures 222 are alternately arranged, but the first island structures 220 and the adjacent second island structures 220 are not aligned. More importantly, each of the first island structures 220 is separated from each of the second island structures 222 by the first trenches 210, while the first island structures 220 are separated from each other by the second trenches 212 and the second island structures 222 are separated from each other by the second trenches 212, as shown in FIGS. 2A and 2B.

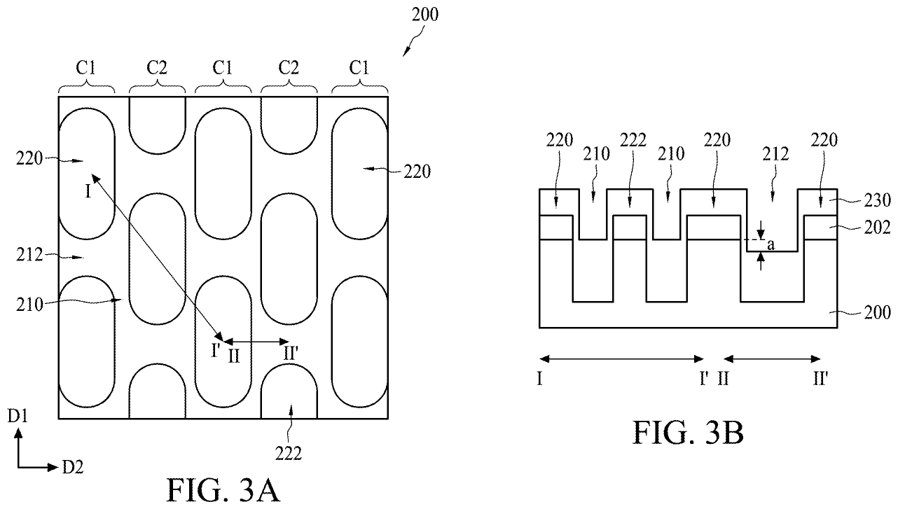

Referring to FIGS. 3A and 3B, a first initially-flowable layer 230 is formed according to step 104. According to step 104, the first initially-flowable layer 230 is formed to partially fill the plurality of first trenches 210 and the plurality of second trenches 212. Therefore, a top surface of the first initially-flowable layer 230 is lower than openings of the plurality of first trenches 210 and openings of the plurality of second trenches 212, as shown in FIGS. 3A and 3B. In some embodiments, the top surface of the first initially-flowable layer 230 in the plurality of first trenches 210 is higher than the top surface of the first initially-flowable layer 230 in the second trench 212. Further, a difference may exist formed between the top surface of the first initially-flowable layer 230 in the plurality of first trenches 210 and the top surface of the first initially-flowable layer 230 in the second trench 212, and the difference a is between approximately 10 m and 50 nm, but the disclosure is not limited thereto. In some embodiments, the first initially-flowable layer 230 includes semiconductor material such as silicon. In some embodiments, the first initially-flowable layer 230 can include flowable semiconductor-containing layer. For example, the first initially-flowable layer 230 can include flowable SiH_{X} or SiH_{X}N, but the disclosure is not limited thereto. In some embodiments, the first initially-flowable layer 230 can be formed by a flowable chemical vapor deposition (flowable CVD), but the disclosure is not limited thereto. In some embodiments, a thickness of the first initially-flowable layer 230 is between approximately 100 nm and approximately 200 nm, but the disclosure is not limited thereto.

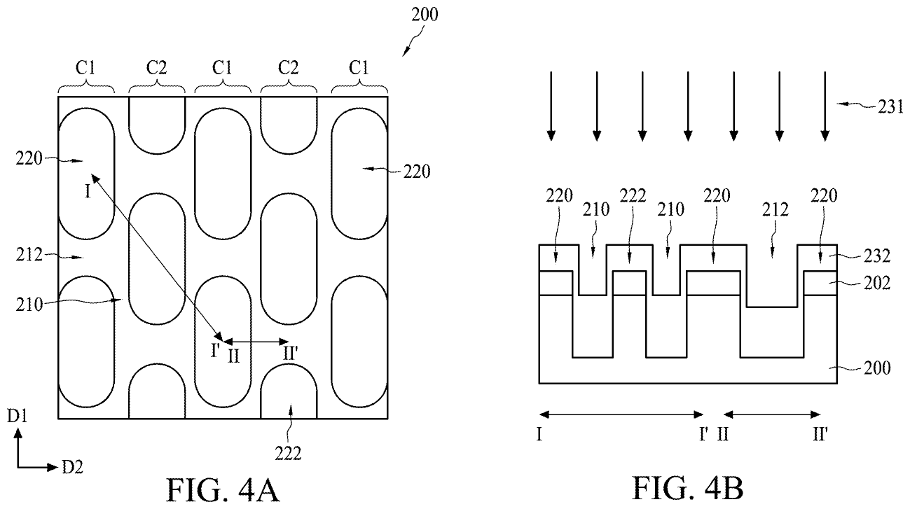

Referring, to FIGS. 4A and 4B, a first treatment 231 is performed on the first initially-flowable layer 230 according to step 106. It should be understood that once the first initially-flowable layer 230 is deposited, it has to be hardened into a solid material. Therefore, the first treatment 231 is provided to transform the first initially-flowable layer 230 into a first dielectric layer 232 in the plurality of first trenches 210 and the plurality of second trenches 212. In some embodiments, the first dielectric layer 232 can include oxygen-containing silicon compound, oxygen-containing SiH layer or oxygen-containing SiH_{X}N_{N} layer, but the disclosure is not limited thereto. In some embodiments, the first treatment 231 can include a thermal treatment, and a temperature of the first thermal treatment 231 is between, for example but not limited thereto, approximately 200° C. and approximately 400° C. In such embodiments, the temperature of the first treatment 231 is high enough to densify the first dielectric layer 232. Further, since the plurality of first trenches 210 and the plurality of second trenches 212 are partially filled, stress generated during the first treatment 231 has less impact on the first and second island structures 220 and 222. In some embodiments, the first treatment 231 can include a UV curing treatment and a wet rinse. In some embodiments, the wet rinse includes wafer rinse. In other embodiments, the first treatment 231 can include an ozone (O₃) treatment.

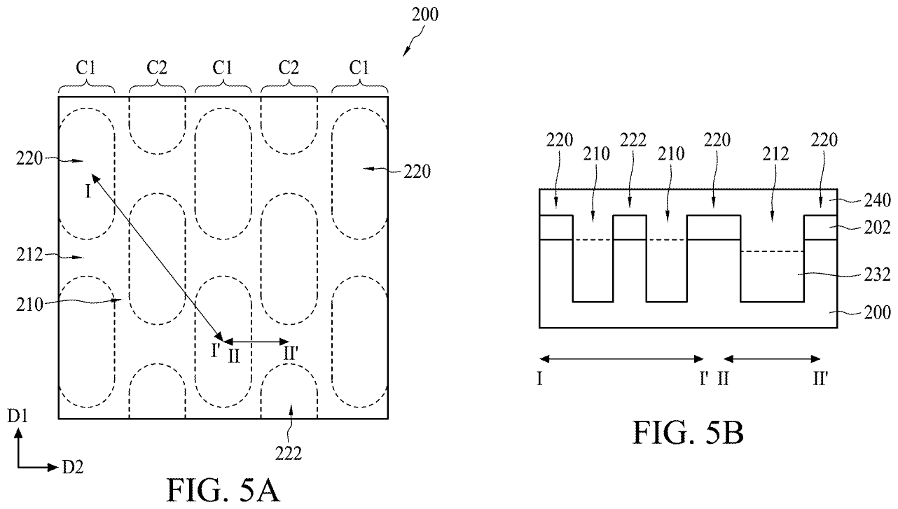

Referring to FIGS. 5A and 5B, a second initially-flowable layer 240 is formed to fill the plurality of first trenches 210 and the plurality of second trenches 212, according to step 108. Accordingly, the partially-filled first and second trenches 210 and 212 are now completely filled by the second initially-flowable layer 240. In some embodiments, the second initially-flowable layer 240 includes semiconductor material such as silicon. In some embodiments, the second initially-flowable layer 240 can include a flowable semiconductor-containing layer. For example, the first initially-flowable layer 240 can include flowable SiH_{X} or SiH_{X}N, but the disclosure is not limited thereto. In some embodiments, the first initially-flowable layer 230 and the second initially-flowable layer 240 can include the same material, but the disclosure is not limited thereto. In some embodiments, the second initially-flowable layer 240 can be formed by a flowable CVD, but the disclosure is not limited thereto. In some embodiments, a thickness of the second initially-flowable layer 240 is between approximately 100 nm and approximately 200 nm, but the disclosure is not limited thereto.

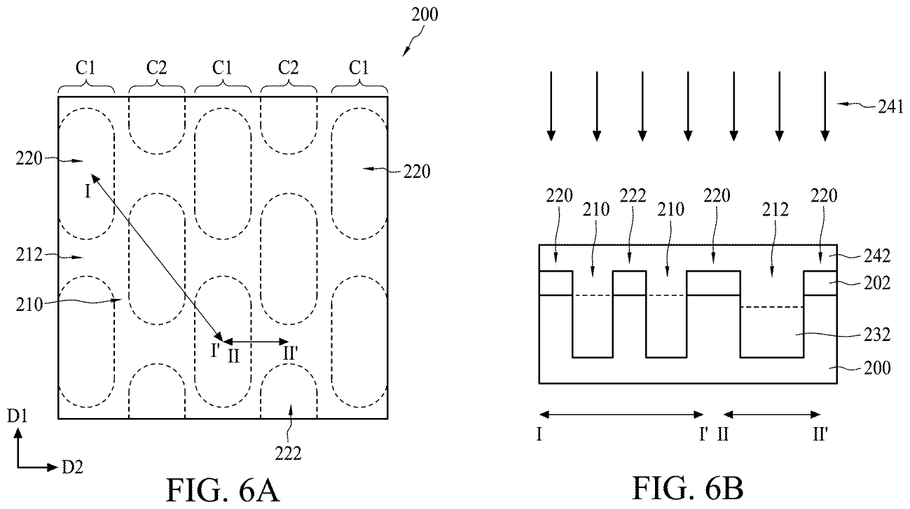

Referring to FIGS. 6A and 6B, a second treatment 241 is performed on the second initially-flowable layer 240 according to step 110. It should be understood that once the second initially-flowable layer 240 is deposited, it has to be hardened into a solid material. Therefore, the second treatment 241 is provided to transform the second initially-flowable layer 240 into a second dielectric layer 242 in the plurality of first trenches 210 and the plurality of second trenches 212. In some embodiments, the second dielectric layer 242 can include oxygen-containing silicon compound, oxygen-containing SiH layer or oxygen-containing SiH_{X}N_{N} layer, but the disclosure is not limited thereto. In some embodiments, the second treatment 241 can include a thermal treatment, and a temperature of the second thermal treatment 241 is lower than the temperature of the first thermal treatment 231. In some embodiments, the temperature of the second thermal treatment 241 is between, for example but not limited thereto, approximately 100° C. and approximately 300° C. In such embodiments, the temperature of the second thermal treatment 241 is lower than the temperature of the first thermal treatment 231 such that stress generated during the second thermal treatment 241 is less than that generated during the first thermal treatment 231. Accordingly, impacts on the first and second island structures 220 and 222, especially the upper portions of the first and second island structures 220 and 222, which are more vulnerable to stress, are reduced. In some embodiments, the second treatment 241 can include a UV curing treatment and a wet rinse. In some embodiments, the wet rinse includes wafer rinse. In other embodiments, the second treatment 241 can include an O₃ treatment. In some embodiments, the first treatment 231 and the second treatment 241 can include the same treatment. In alternative embodiments, the first treatment 231 and the second treatment 241 can include different treatments.

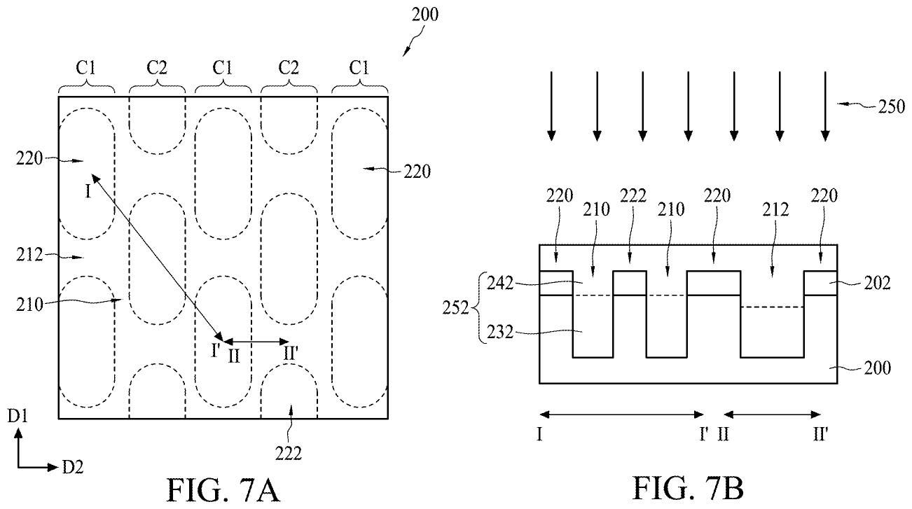

Referring to FIGS. 7A and 7B, a densification 250 can be performed. Accordingly, the first and second dielectric layers 232 and 242 are further densified, and thus a dielectric structure 252 is obtained. Accordingly, the plurality of first trenches 210 and the plurality of second trenches 212 are all filled with the dielectric structure 252, as shown in FIGS. 7A and 7B.

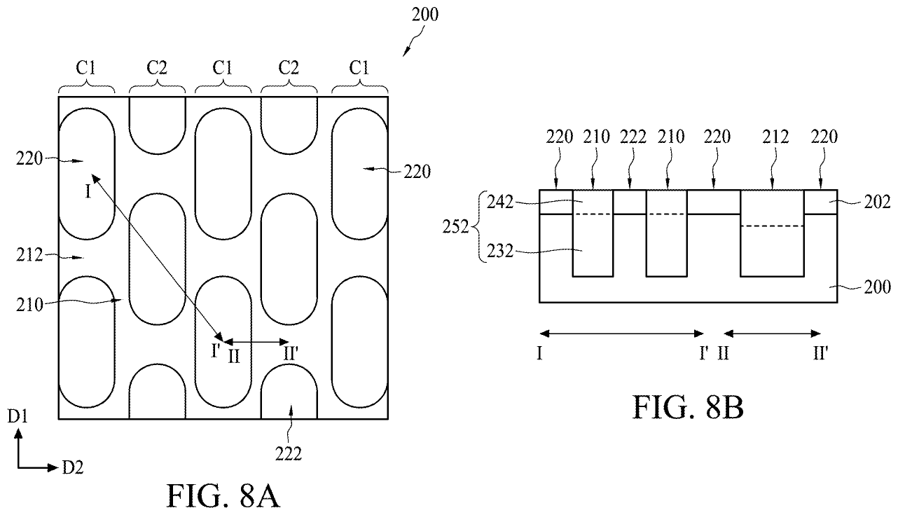

Referring to FIGS. 8A and 8B, in some embodiments, a planarization such as chemical mechanical planarization (CMP) is performed after the forming of the dielectric structure 252. Accordingly, a portion of the dielectric structure 252 (i.e., the second dielectric layer 242) is removed from the substrate 200. As a result, the patterned hard mask 202 on the first and second island structures 220 and 222 is exposed, and the first and second island structures 220 and 222 are separated from each other by the dielectric structure 252 including the first dielectric layer 232 and the second dielectric layer 242. In some embodiments, a top surface of the patterned hard mask 202 and topmost portions of the dielectric structure 252 (i.e., the second dielectric layer 242) are coplanar, but the disclosure is not limited thereto.

According to the method 10, the plurality of first trenches 210 and the plurality of second trenches 212 are partially filled with the first initially-flowable layer 230 and then completely filled with the second initially-flowable layer 240. In other words, the dielectric structure 252 is formed by two steps according to the method 10. By individually forming the first and second initially-flowable layers 230 and 240, and individually performing the first and second treatments 231 and 241 to transform the first and second initially-flowable layers 230 and 240 into the first and second dielectric layers 232 and 242, stress generated during the transforming is reduced without incurring the void issue. Therefore, collapse issue is mitigated, and reliability and performances of the devices that include the first and second island structures 220 and 222 are improved.

In contrast, with a comparative method applied with forming the dielectric structure in one step, the dielectric structure used to isolate semiconductor structures faces a necessary compromise. To provide sufficient electrical isolation, a higher temperature is required to form a dense structure; however, significant stress is generated at the higher temperature, and causes collapse issue. To avoid the collapse issue, a lower temperature is required, but the dielectric structure then suffers from void issue and poor electrical isolation. Eventually, the semiconductor structures suffer from either the collapse issue or from poor electrical isolation.

One aspect of the present disclosure provides a method for preparing semiconductor structures. The method includes the following steps: A substrate is provided. A plurality of first trenches are formed in the substrate. A first initially-flowable layer is formed in the plurality of first trenches. A top surface of the first initially-flowable layer is lower than openings of the plurality of first trenches. A first treatment is performed on the first initially-flowable layer to form a first dielectric layer in the plurality of first trenches. A second initially-flowable layer is formed to fill the plurality of first trenches. A second treatment is performed on the second initially-flowable layer to form a second dielectric layer in the plurality of first trenches.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method for preparing semiconductor structures, comprising:
providing a substrate;
forming a plurality of first trenches in the substrate;
forming a first layer in the plurality of first trenches, wherein a top surface of the first initially-flowable layer is lower than openings of the plurality of first trenches;
performing a first treatment on the first initially-flowable layer to form a first dielectric layer in the plurality of first trenches;
forming a second initially-flowable layer to fill the plurality of first trenches; and
performing a second treatment on the second initially-flowable layer to form a second dielectric layer in the plurality of first trenches.

2. The method of claim 1, wherein the first treatment comprises a first thermal treatment.

3. The method of claim 2, wherein the second treatment comprises a second thermal treatment, and a temperature of the second thermal treatment is lower than a temperature of the first thermal treatment.

4. The method of claim 3, wherein the temperature of the first thermal treatment is between approximately 200° C. and approximately 400° C.

5. The method of claim 3, wherein the temperature of the second thermal treatment is between approximately 100° C. and approximately 300° C.

6. The method of claim 1, wherein the first treatment comprises a UV curing treatment and a wet rinse.

7. The method of claim 1, wherein the first treatment comprises an ozone (O₃) oxidation.

8. The method of claim 1, wherein the second treatment comprises a UV curing treatment and a wet rinse.

9. The method of claim 1 wherein the second treatment comprises an ozone (O₃) oxidation.

10. The method of claim 1, further comprising forming a plurality of second trenches in the substrate simultaneously with the forming of the plurality of first trenches.

11. The method of claim 10, wherein a width of the plurality of second trenches is greater than a width of the plurality of first trenches.

12. The method of claim 10, wherein the first initially-flowable layer is formed in the plurality of second trenches, and a top surface of the first initially-flowable layer is lower than an opening of the plurality of second trenches.

13. The method of claim 12, wherein the top surface of the first initially-flowable layer in the plurality of first trenches is higher than the top surface of the first initially-flowable layer in the plurality of second trenches.

14. The method of claim 13, wherein a difference exists between the top surface of the first initially-flowable layer in the plurality of first trenches and the top surface of the first initially-flowable layer in the plurality of second trenches, and the difference is between approximately 10 nm and approximately 50 nm.

15. The method of claim 1, wherein the first initially-flowable layer and the second initially-flowable layer comprise a flowable semiconductor-containing layer.

16. The method of claim 15, wherein the first initially-flowable layer and the second initially-flowable layer comprise a same material.

17. The method of claim 1, further comprising performing a densification after the forming of the second dielectric layer.

18. The method of claim 1, further comprising performing a planarization after the forming of the second dielectric layer.
